(19) United States
(12) Patent Application Publication
(10) Pub. No.: US 2024/0054257 A1
(43) Pub. Date: Feb. 15, 2024

(54) ENGINEERING A PHYSICAL SYSTEM, METHOD, AND SYSTEM

(71) Applicant: Siemens Industry Software GmbH, Zurich (CH)

(72) Inventor: Nikolay Entin, Stuttgart (DE)

(21) Appl. No.: 18/233,284

(22) Filed: Aug. 11, 2023

Related U.S. Application Data
(63) Continuation of application No. PCT/EP2022/072558, filed on Aug. 11, 2022.

(51) Int. Cl. G06F 30/17; G06F 30/12

(52) U.S. Cl. CPC G06F 30/17; G06F 30/12

(57) ABSTRACT

For an improved engineering of a physical system, a method includes providing engineering information, lifecycle information and at least one test case in an engineering database. The engineering information is related to physical, mechanical, electrical, electronic, hydraulic, thermal, control, electric power, and/or process-oriented information of the physical system. The lifecycle information is related to conception, requirements, use cases, issues, design, realization, and/or service information of the physical system. A respective engineering artifact included by the engineering information, a respective lifecycle artifact included by the lifecycle information, and/or a compliance of the respective engineering artifact with the respective lifecycle artifact may be tested using the respective test case. The test may be performed using the respective test case, and a respective test result may be generated in the engineering database, respectively. The respective test result is linked to the respective lifecycle artifact stored in the lifecycle database, respectively.

This application is a continuation of International Patent Application No. PCT/EP2022/072558, filed on Aug. 11, 2022, which is hereby incorporated by reference in its entirety.

### TECHNICAL FIELD

Embodiments relate to engineering systems, engineering management systems, systems engineering systems, and similar systems, such as computer-aided design (CAD), computer-aided manufacturing (CAM), computer-aided engineering (CAE), and electronic design automation (EDA), that are used to design, integrate, and manage physical systems, such as machines, structures, and other items, including bridges, tunnels, roads, vehicles, and buildings. Further embodiments relate to product lifecycle management (PLM) systems, application lifecycle management (ALM) systems (e.g., for software), artifact information systems, and similar systems that are used to create, use, and manage data for products including software and artifacts and other items. The mentioned systems are collectively referred to herein as product systems. Further, the present disclosure is directed, in general, to the interplay of the mentioned engineering systems and the PLM or ALM systems.

### BACKGROUND

Product systems may include stored content associated with physical systems and product lifecycle information of physical systems. Such content may include engineering information and lifecycle information of the physical system to be engineered.

Currently, there exist product systems and solutions that support engineering a physical system. Such product systems may benefit from improvements.

### SUMMARY

Variously disclosed embodiments include data processing systems and methods that may be used to facilitate engineering a physical system, especially managing of engineering-related test cases.

According to a first aspect, a computer-implemented method of engineering a physical system is provided. The computer-implemented method includes: providing engineering information, lifecycle information, and at least one test case in an engineering database. The engineering information is related to physical, mechanical, electrical, electronic, hydraulic, thermal, control, electric power, and/or process-oriented information of the physical system. The lifecycle information is related to the conception, requirements, uses cases, issues, design, realization, and/or service information of the physical system. A respective engineering artifact included by the engineering information, a respective lifecycle artifact included by the lifecycle information, and/or a compliance of the respective engineering artifact with the respective lifecycle artifact may be tested using the respective test case. The lifecycle information is provided in a lifecycle database. The test is performed using the respective test case, and a respective test result is generated in the engineering database, respectively. The respective test result is stored in the lifecycle database, and the respective test result is linked to the respective lifecycle artifact stored in the lifecycle database, respectively.

According to a second aspect, a computer system may be arranged and configured to execute the acts of the computer-implemented method according to the first aspect.

According to a third aspect, a computer program product may include computer program code that, when executed by the computer system according to the second aspect, causes the computer system to carry out the method according to the first aspect.

According to a fourth aspect, a computer-readable medium may include the computer program product according to the third aspect. By way of example, the described computer-readable medium may be non-transitory and may further be a software component on a storage device.

### BRIEF DESCRIPTION OF THE DRAWINGS

FIGS. 1-6 depict a functional block diagram of example systems that facilitate engineering a physical system in a product system according to an embodiment.

FIG. 7 depicts example relations of engineering information, test cases, and test results in the context of facilitating engineering a physical system in a product system according to an embodiment.

FIGS. 8 and 9 depict a schematic block diagram of example systems that facilitate engineering a physical system in a product system according to an embodiment.

FIG. 10 depicts a sample UI that facilitate engineering a physical system in a product system according to an embodiment.

FIG. 11 depicts a flow diagram of an example methodology that facilitates engineering a physical system of a product system according to an embodiment.

FIG. 12 depicts a block diagram of a data processing system according to an embodiment.

### DETAILED DESCRIPTION

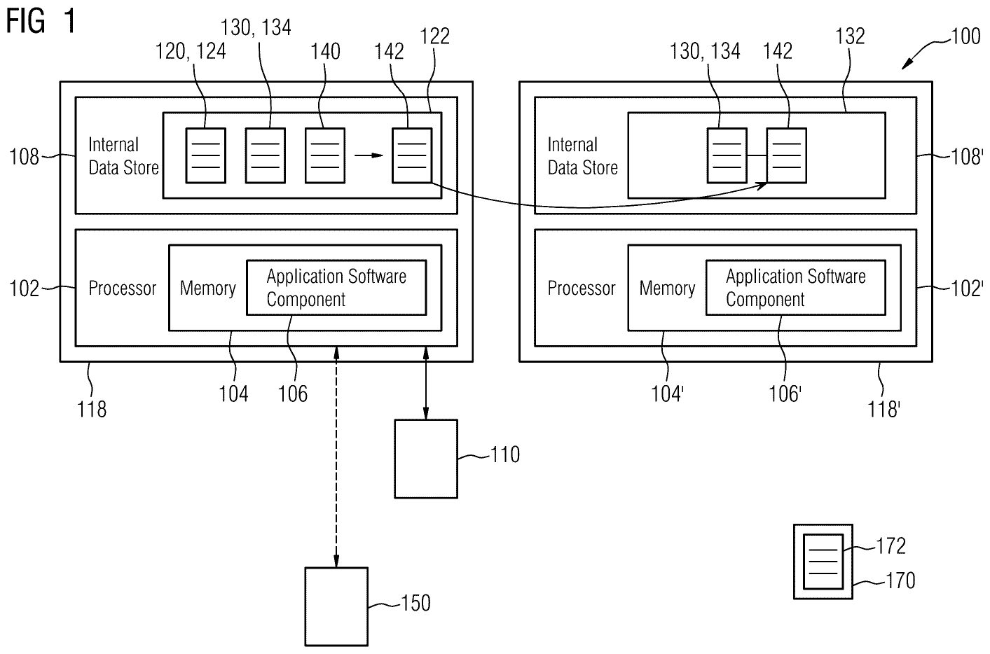

With reference to FIG. 1, a functional block diagram of an example data processing system 100 is depicted that facilitates engineering a physical system 150 in a product system. The data processing system 100 may, in some examples, include an engineering system 118 and a product lifecycle management system 118′. The engineering system 118 and the product lifecycle management system 118′ may, by way of example, each include at least one processor 102, 102′ that is configured to execute at least one respective application software component 106, 106′ from a respective memory 104, 104′ accessed by the respective processor 102, 102′. The respective application software component 106, 106′ may be configured (e.g., programmed) to cause the respective processor 102, 102′ to carry out various acts and functions described herein. For example, the described application software component 106, 106′ may include and/or correspond to one or more components of an engineering software application or to a PLM or ALM software application that is configured to generate and store product data in a data store 108, 108′ such as a database, respectively.

In some examples, the engineering system 118 may allow for the engineering a physical system 150 by providing corresponding functionalities to a user and by creating, amending, or managing corresponding engineering information 120 relating to the physical system 150. The product lifecycle management system 118′ may, for example, allow for the management of lifecycle information 130 by providing corresponding functionalities to a user and by creating, amending, or managing corresponding lifecycle information 130 relating to the physical system 150. By way of example, the engineering information 120 may relate to physical, mechanical, electrical, electronic, hydraulic, thermal, control, electric power, and/or process-oriented information of the physical system. In further examples, the engineering information 120 may relate to an architecture (e.g., software architecture) of the physical system 150. Further, the lifecycle information 130 may, for example, relate to or include the conception, requirements, uses cases, issues, design, realization and/or service information of the physical system 150. In further examples, the lifecycle information 130 may, for example, include data records representing/storing data corresponding to parts, tools, documents, process descriptions, templates, materials, requirements specifications, software products, or software applications relating to the physical system 150, respectively.

In further embodiments, at least one test case 140 relating to the physical system 150 or at least certain aspects of the physical system 150 may be used to qualify the physical system 150 as compliant with certain requirements or specifications or to find issues of the physical system 150. Such a test case 140 may include or relate, for example, to test information or test management information, and may further include at least one test criterion against which the physical system 150 (e.g., certain engineering information 120 and/or lifecycle information 130 relating to the physical system 150) may be tested.

The result of the execution of the respective test case 140 (e.g., in a very simple example “passed” or “failed”) may be stored as a respective test result 142. Further, by way of example, such a test case 140 may be available for different variants of the physical system 150 (e.g., standard, premium, luxury variants of a car, low-, middle, high-power output machines, etc.). An issue identified for at least one variant of the physical system 150 using the test case 140 may equally apply to the other variants of the physical system 150. Hence, an issue identified for at least one variant of the physical system 150 may easily be checked or verified for the other variants of the physical system 150.

In some examples, the physical system 150 may include or be a sensor, an actuator, such as an electric motor, a valve or a robot, an inverter supplying an electric motor, a gear box, a programmable logic controller (PLC), a communication gateway, and/or other parts or components relating to industrial automation products and industrial automation in general. The physical system 150 may be part of a complex production line or production plant (e.g., a bottle filing machine, conveyor, welding machine, welding robot, etc.). In some examples, the physical system 150 may be a smartphone, smartwatch, handheld, pad, laptop or the like, or a desktop device (e.g., including desktop computers, or other “smart” devices, such as smart television sets, fridges, home or industrial automation devices). Smart television sets may, for example, be a television set with integrated Internet capabilities or a set-top box for television that offers more advanced computing ability and connectivity than a contemporary basic television set. Further, by way of example, the physical system 150 may include or be any machine, structure, or other items, including bridges, tunnels, roads, vehicles, and buildings, that may be engineered.

Examples of engineering systems that may be adapted to include some of the engineering features described herein may include Simcenter Amesim, an application produced by Siemens Industry Software NV, of Leuven, Belgium, the NX suite of applications or Solid Edge applications produced by Siemens Industry Software Inc., of Plano, Texas, USA or the Totally Integrated Automation (TIA) Portal, an application produced by Siemens Aktiengesellschaft, of Munich, Germany. Examples of PLM systems that may be adapted to support the engineering features described herein may include the Active Workspace features of Teamcenter, an application produced by Siemens Industry Software Inc., of Plano, Texas, USA. Examples of ALM systems that may be adapted to support the engineering features described herein may include Polarion ALM, an application produced by Siemens Industry Software GmbH, of Zurich, Switzerland. However, the systems and methods described herein may be used in other product systems (e.g., PLM, PDM, ALM systems) and/or any other type of system that generates and stores product data in a database. Also, examples of databases that may be used as one or more data stores described herein include database server applications such as Oracle, Microsoft SQL Server, or any other type of data store that is operative to store data records.

By way of example, the data processing system 100 may be cloud-based, internet-based and/or be operated by a provider providing engineering support. The user may be located close to the data processing system 100 or remote to the data processing system 100 (e.g., anywhere else) using, for example, a mobile device for connecting to the data processing system 100 (e.g., via the internet). The device of the user may include an input device 110 and a display device 112. In some examples, the data processing system 100 (e.g., the engineering system 118 and/or the product lifecycle management system 118′) may be installed and run on a device of the user, such as a computer, laptop, pad, on-premises computing facility, or the like.

It may be difficult and time-consuming to engineer a physical system 150 in complex, production engineering, PLM or ALM environments. For example, amendments may be made to some of the engineering information 120 or to some of the information related to the physical system 150 stored in an engineering database 122, and these amendments may not be taken into account by the corresponding lifecycle information 130 or information related to the physical system 150 stored in a lifecycle database 132. A similar challenge may occur, for example, in the context of the respective test case 140 and/or the respective test result 142 (e.g., when amendments to the respective test case 140 are made, or more recent, respective test result 142 are available). However, consistence with respect to the engineering information 120 and the lifecycle information 130 of the physical system 150 as well as respective test case 140 and respective test result 142 may be provided to enable a successful engineering process and a successful design or production or manufacture of the physical system 150. According to other approaches, achieving consistency between the engineering information 120 and the lifecycle information 130 of the physical system 150 may require many consciously and carefully performed manual steps that provide an error-prone, slow, and not efficient process.

To enable the enhanced engineering of a physical system 150, the described data processing system 100 or, for example, the engineering system 118, may include at least one input device 110 and at least one display device 112 (e.g., a display screen). The described processor 102 may be configured to generate a graphical user interface (GUI) 114 through the display device 112. Such a GUI may include GUI elements such as buttons, links, search boxes, lists, text boxes, images, scroll bars usable by a user to provide inputs through the input device 110 that cause managing artifact information. In the GUI, an engineering user interface 116 and/or a lifecycle user interface 116′ may be displayed to a user.

In some examples, the application software component 106 and/or the processor 102 may be configured to provide engineering information 120, lifecycle information 130, and at least one test case 140 in an engineering database 122. Herein, the engineering information 120 may be related to physical, mechanical, electrical, electronic, hydraulic, thermal, control, electric power, and/or process-oriented information of the physical system 150. The engineering database 122 may, by way of example, be included in the data store 108 of the engineering system 118 or more generally of the data processing system 100. In some examples, the engineering information 120 may characterize the geometric shape, the surface quality, the stiffness, electric, magnetic, and/or thermal conductivity of the physical system 150. Further, the engineering information 120 may include information on controlling the physical system 150 or on controlling a process (e.g., a production process) using the physical system 150. Generally, the engineering information 120 may directly relate to the physical system 150 or to one or more components of the physical system 150. In some examples, the engineering database 122 may be included in an engineering system 118.

Further, the lifecycle information 130 may, for example, be related to the conception, requirements, uses cases, issues, design, realization, and/or service information of the physical system 150. Herein, the conception may relate to information on the physical system 150 that have been created during the ideation (e.g., in an early phase of the creation of the physical system 150). The requirements may include or be a physical or functional need that the physical system 150 aims to satisfy. The requirements may, for example, describe any necessary (or sometimes desired) function, attribute, capability, characteristic, or quality of the physical system 150 for it to have value and utility to a customer, organization, internal user, or other stakeholder. By way of example, the requirements may define characteristics that the physical system 150 shall have or comply with, such as output power, maximum weight, surface quality, compliance with safety regulations, etc. Use cases of the physical system 150 may include a usage scenario for the physical system 150, such as the employment of the physical system 150 at a certain industrial environment (e.g., a conveyor, paper machine, etc.) that may influence or determine certain properties or requirements of the physical system 150. Use cases may further include potential scenarios in that the physical system 150 receives an external request, such as user input or sensor or control data, and responds to the external request. Hence, such a potential scenario may involve a response function that the physical system 150 has in reply to given input data. Issues may, by way of example, relate to potential deficiencies or customer complaints with respect to the physical system 150 or functionalities or components of the physical system 150. Hence, such issues may also influence or determine certain properties or requirements of the physical system 150. Further, the design may relate to the geometrical, visual of physical appearance of the physical system 150. The design may further be or include a plan or specification for the construction of the physical system 150 or for the implementation of an activity or process relating to the physical system 150, or the result of that plan or specification in the form of a prototype, product, or process. Herein, the design may need to satisfy certain goals and constraints, such as the requirements, and may need to take into account aesthetic, functional, economic, or socio-political considerations, and is expected to interact with a certain environment. Examples of designs include architectural blueprints, engineering drawings, business processes, circuit diagrams, and sewing patterns. The realization may relate to the manufacturing or the production of the physical system 150 and, in some examples, include information on how to manufacture or produce the physical system 150 and how to achieve the desired characteristics of the physical system 150, such as surface quality so that compliance with the above-mentioned requirements may be achieved. Service information may describe how the physical system 150 needs to be serviced (e.g., which maintenance intervals apply) and which maintenance activities need to be carried out to allow for reliable and long-lived operation of the physical system 150.

Additionally, the lifecycle information 130 may include software documentation, software applications, complex data objects, work items, tasks, change requests, defects or test cases, source code of software products, images, videos, text, webpages, documentation, or any combination thereof relating to the above-explained lifecycle information 130 of the physical system 150. Such lifecycle information 130 may, for example, be used in the context of (agile) software or hardware development.

In some examples, a respective test case 140 may be used to test (e.g., some of) the engineering information 120 and/or (e.g., some of) the lifecycle information 130. Herein, the engineering information 120 may include one or more engineering artifacts 124, and the lifecycle information 130 may include one or more lifecycle artifacts 134. The respective test case 140 may then, for example, be used to test the respective engineering artifact 124 and/or the respective lifecycle artifact 134, for example, with respect to self-consistency or certain test criteria included as test information or test management information in the respective test case 140. In some examples, the respective test case 140 may be used to test a compliance of the respective engineering artifact 124 with the respective lifecycle artifact 134.

In some examples, the described engineering information 120, the described lifecycle information 130, and the described test case 140 may be tightly connected to each other. In some examples, the lifecycle information 130 including the respective lifecycle artifact 134 may be implemented by the engineering information 120 including the respective engineering artifact 124, where the lifecycle information 130 or, more specifically, the respective lifecycle artifact 134 may be verified with the respective test case 140 through the test. In further examples, alternatively or additionally, the engineering information 120 or more specifically the respective engineering artifact 124 may be verified with the respective test case 140 through the test. Herein, the described verification or implementation may involve linking or connecting the concerned items (e.g., for easy and convenient data exchange or data processing).

Further, changes to the lifecycle information 130 may, in many examples, require changes to the engineering information 120 and vice versa. Further, changes to the lifecycle information 130 may, in many cases, require changes to the respective test case 140 and vice versa. Hence, there may be an interplay between the engineering information 120, the lifecycle information 130, and the respective test case 140 that reflects the fact that both the engineering information 120 and the lifecycle information 130 may characterize the physical system 150 or parts of the physical system 150 and that the respective test case 140 may be essential to verify the engineering information 120 and/or the lifecycle information 130 (e.g., by checking the compliance of the engineering information 120 and/or the lifecycle information 130 with important test criteria).

By way of example, the respective lifecycle artifact 134 may include the requirement that the physical system 150 (e.g., a car) has a maximum speed of at least 140 km/h. A suitable engineering artifact 124 of the physical system 150, for example, being related to the maximum power of the engine or traction motor, may be tested according to a suitable, related test case 140 (e.g., if the engineering artifact 124 complies (is suitable to fulfil) the (requirement included in the) respective lifecycle artifact 134).

In another example, the lifecycle information 130 and/or the respective test case 140 may relate to safety standards that need to be complied with by safety-critical systems to reach certification. As an example, such a standard may be ISO 26262, titled “Road vehicles—Functional safety,” which is an international standard for functional safety of electrical and/or electronic systems that are installed in serial production road vehicles (e.g., excluding mopeds). Another example of such a standard may be IEC 61508, titled “Functional Safety of Electrical/Electronic/Programmable Electronic Safety-related Systems (E/E/PE, or E/E/PES).” By way of example, the respective test case 140 may include mandatory features described in the respective standard and the respective requirements artefact 134, and/or the respective engineering artefact 124 may be tested against the mentioned mandatory features that are included in the respective test case 140.

By way of example, the respective test case may include additional test information that may be required to suitably link and test the respective engineering artifact 124 and the respective lifecycle artifact 134. The results of the respective performed test case 140 may then be stored as a respective test result 142 that may, for example, include rather basic information such as “passed,” “fulfilled,” or “compliant” for a positive test outcome or “failed,” “violated,” “noncompliant” for a negative test outcome. In more advanced examples, the respective test result 142 may include information on which aspect of the test case 140 was successful or unsuccessful and may provide reasons or generally more details, respectively.

In some examples, the application software component 106 and/or the processor 102 may further be configured to provide the lifecycle information 130 in a lifecycle database 132. The lifecycle database 132 may, for example, be included in a product lifecycle management system 118′ that may be different from the engineering system 118. Accordingly, the engineering database 122 may be different from the lifecycle database 132 that are stored in different data stores 108, 108′, respectively. In further examples, the lifecycle database 132 may be stored in the same data store 108 as the engineering database 122, and the processor 102 may be used by both the engineering system 118 and the product lifecycle management system 118′.

By way of example, the application software component 106 and/or the processor 102 may further be configured to perform the test using the respective test case 140 and to generate a respective test result 142 in the engineering database 122, respectively.

The respective test may then be executed (e.g., the respective test case 140 may be used to perform the test). Herein, the input data of the respective test may be the respective test case 140, and additionally, the respective engineering artifact 124 and/or the respective lifecycle artifact 134. Further, the output data of the respective test may be the respective test result 142, such as “passed” or “failed,” optionally with additional information as explained above. In some examples, the respective test result 142 may be stored in the engineering database 122, whereby the respective test may be executed by the engineering system 118 (e.g., in a test software module or a test manager software module that is included in the engineering system 118).

In some examples, the application software component 106 and/or the processor 102 may further be configured to store the respective test result 142 in the lifecycle database 132 and to link the respective test result 142 to the respective lifecycle artifact 134 stored in the lifecycle database 132, respectively.

In some examples, the respective test result 142 may be imported or copied from the engineering database 122 to the lifecycle database 132 so that the respective test result 142 may then be available in the lifecycle database 132 and optionally the lifecycle management system 118′. In the lifecycle database 132, the respective test result 142 may then be linked to the respective lifecycle artifact 134. This allows the user of the lifecycle management system 118′ to easily see or check whether for a given lifecycle artifact 134, a suitable test result 142 is available and if applicable what the test result 142 is.

Hence, the availability of the respective test result 142 in the lifecycle database 132 and the link of the respective test result 142 with the respective lifecycle artifact 134 in the lifecycle database 132 may, for example, improve the traceability and the verifiability, but also the persistence of the engineering process of the physical system 150. In some examples, the data stored in the engineering database 122 or the engineering system 118 may not be stored persistently so that during or long time after completion of the engineering process of the physical system 150, some data (e.g., relating to an earlier engineering status or to the sequence of amendments made to the engineering information 120 and/or the lifecycle information 130) may get lost or overwritten. The lifecycle database 132 and/or the lifecycle management system 118′, however, may, for example, involve persistent data storage so that the data stored in the lifecycle database 132, such as the lifecycle information 130, the imported test result 142, etc. including their respective state or version, may outlive (e.g., persists more than) the process that created the data (e.g., the engineering process of the physical system 150). This may be achieved in practice, for example, by storing the state as data in computer data storage (e.g., the respective state or version of the lifecycle information 130 and the imported test result 142 in the lifecycle database 132). Hence, in some examples, the single point of trust or sometimes referred to as the single source of truth may be realized by the lifecycle database 132. In further examples, the single point of trust or the single source of truth may be realized by the combination of the lifecycle database 132 and the engineering database 122.

For example, checking if the respective lifecycle artifact 134 complies with the above-mentioned safety standards or checking if the respective engineering artifact 124 complies with the respective lifecycle artifact 134 may be considerably facilitated and at the same time made persistent through the storage and linkage of the respective test result 142 to the respective lifecycle artifact 134 in the lifecycle database 132. This is of particular importance, for example, if safety issues occur with the engineered physical system 150 and the task is to retrace the complete engineering process of the physical system 150 and to find out when, how, and/or by who the potential mistake has been made in the engineering process of the physical system 150.

In some examples, the link of the respective test result 142 to the respective lifecycle artifact 134 in the lifecycle database 132 may be a direct link (e.g., with no intermediary items between the respective test result 142 and the respective lifecycle artifact 134 in the lifecycle database 132), or this link may be an indirect link (e.g., with one or more intermediary items between the respective test result 142 and the respective lifecycle artifact 134 in the lifecycle database 132). Hereby, the indirect link may, for example, be such that the respective test result 142 is linked to the respective test case 140, and the respective test case 140 is linked with the respective lifecycle artifact 134 in the lifecycle database 132, whereby the three mentioned items are all stored in the lifecycle database 132.

In some examples, the respective test result 142 may also be stored in the engineering database 122. In further examples, the respective test result 142 and optionally the respective lifecycle artifact 134 may be displayed to the user of the lifecycle database 132 or the lifecycle management system 118′ in a lifecycle user interface 116′.

In further examples, the respective test case 140 may be developed in the engineering system 118 that may provide support and tools to a user for developing or managing the respective test case 140. By way of example, two or more respective test results 142 including the results of individual tests may be combined to a test report. The respective two or more test cases 140 and optionally the corresponding two or more test results 142 may sometimes also be referred to as a test run.

In some examples, the application software component 106 and/or the processor 102 may further be configured to: provide a respective lifecycle test case 140L in the lifecycle database 132; and import the respective lifecycle test case 140L from the lifecycle database 132 to the engineering database 122 and to store the respective lifecycle test case 140L in the engineering database 122 as the respective test case 140.

The provision of the respective lifecycle test case 140L in the lifecycle database 132 may, for example, be done through user interaction with the lifecycle database 132 or the lifecycle management system 118′, whereby the lifecycle database 132 or the lifecycle management system 118′ may offer suitable support and tools to develop or at least manage this suitable, respective lifecycle test case 140L. In some examples, the respective lifecycle test case 140L may closely relate to the lifecycle information 130 or more particularly to the respective lifecycle artifact 134 (e.g., such that the respective lifecycle artifact 134 may be a requirement to be fulfilled by the physical system 150, such as a length, a weight, an electric output power, etc.). The respective lifecycle test case 140 may simply be a check if the physical system 150, the engineering information 120, the corresponding, respective engineering artifact 124, the lifecycle information 130, and/or the respective lifecycle artifact 134 comply with the mentioned requirement.

The respective lifecycle test case 140L may then be imported from the lifecycle database 132 to the engineering database 122 where the respective lifecycle test case 140L may be stored as the respective test case 140 that may then be used for performing the above-described test. In further examples, the respective lifecycle test case 140L stored in the lifecycle database 132 and the respective lifecycle artifact 134 stored in the lifecycle database 132 may be linked so that a good and reliable traceability between the respective lifecycle artifact 134, the respective lifecycle test case 140L, and the respective test result 142 that are stored in the lifecycle database 132 may be achieved. In some examples, the respective lifecycle test case 140L stored in the lifecycle database 132 and the respective lifecycle artifact 134 stored in the engineering database 122 may be linked, which may facilitate updating the respective entity in the one of the two databases if an amendment of our relate to the respective entity in the outdoor of the two databases.

In some examples, the respective test case 140 may be developed in a separate system, such as a system specialized on creating meaningful test cases 140. If the respective test case 140 originates from a separate system, the respective test case 140 may, in some examples, be imported from the separate system to the lifecycle database 132 and then from the lifecycle database 132 to the engineering database 122.

In some examples, the application software component 106 and/or the processor 102 may further be configured to provide at least one parameter of the respective test case 140 in the engineering database 122. The respective parameter includes input data, expected output data, a number of repetitions, information on a callback, or any combination thereof.

By way of example, the user of the engineering database 122 or the engineering system 118 may provide his or her input to parametrize the respective test case 140. Parametrization may, in some examples, be required for a respective test case 140 that may rather be conceptual, generic, or high-level so that the specific adaptation of the respective test case 140 to the specific physical system 150, the specific engineering information 120, and/or the specific lifecycle information 130 may be required.

The input data may specifically define what aspect (e.g., which physical entity) of the respective engineering artifact 124 and/or the respective lifecycle artifact 134 shall be used as input of the test and therefore, in some examples, shall be tested. The expected output data may define the expected output in case of a successful test and may, by way of example, include specific values of the physical entities. If the output of the performed test is equal to the expected output data (e.g., within acceptable deviations), then the performed test may be considered to be successful, and the above-described compliance may be confirmed, which may be documented (e.g., by storing corresponding information as the respective test result 142). By way of example, the output of the performed, respective test may be additionally stored in the respective test result 142, optionally along with the expected output and/or the input data. Further, the number of repetitions of the test may define often the test needs to be repeated that may, in some examples, be required to comply with safety standards in the context of safety-critical systems. The information on a callback may indicate any reference to executable code (e.g., included in the respective engineering artifact 124) that is passed as an argument to another piece of code (e.g., included in a different engineering artifact 124′), and that may, for example, be relevant information to identify existing dependencies. Hence, the information on a callback may, for example, be used to verify required dependencies and to make sure only the required dependencies exist.

In some examples, the above-described respective lifecycle test case 140L that has been imported from the lifecycle database 132 to the engineering database 122 and that has been stored in the engineering database 122 as the respective test case 140 may require the above-described parametrization in the engineering database 122. This may, for example, be the case if the respective lifecycle test case 140L has been provided in the lifecycle database 132 in a rather conceptual, generic, or high-level way.

In further examples, the application software component 106 and/or the processor 102 may further be configured to: store the provided, respective parameter of the respective test case 140 in the lifecycle database 132; and link the respective parameter of the respective test case 140 to the respective test case 140 stored in the lifecycle database 132.

Importing the provided, respective parameter of the respective test case 140 from the engineering database 122 to the lifecycle database 132 may, for example, further improve the traceability and the verifiability, but also the persistence of the engineering process of the physical system 150. In some examples, the respective parameter stored in the engineering database 122 and the respective parameter stored in the lifecycle database 132 may be linked, which may facilitate updating the respective parameter stored in the lifecycle database 132 when the respective parameter stored in the engineering database 122 has been changed.

In some examples, the application software component 106 and/or the processor 102 may further be configured to: provide a lifecycle user interface (UI) 116′ to a user for interacting with the lifecycle database 132; capture the user's intent to trigger performing the test using the respective test case 140 and generating a respective test result 142 in the engineering database 122, respectively; and perform the test using the respective test case 140 and generating a respective test result 142 in the engineering database 122, respectively, upon the captured user intent.

The lifecycle UI 116′ may be provided to a user of the lifecycle database 132, whereby in some examples, the user may, at the same time, use the lifecycle database 132 and the engineering database 122, so that the lifecycle UI 116′ may also include some functionalities or data provided by the engineering database 122 or the engineering system 118. By way of example, a UI element 137 may be displayed in the lifecycle UI 116′, and the user may select or click on the UI element 137 to provide his or the input to trigger performing the test using the respective test case 140 and generating the respective test result 142 in the engineering database 122. Once the corresponding user intent has been captured, for example, by the lifecycle database 132 or the lifecycle management system 118′, the test may be performed accordingly in the engineering database 122.

In these examples, a user managing lifecycle information 130 in the lifecycle database 132 may trigger the test to be performed in the engineering database 122. Hence, triggering to perform the test and, as described above, importing the corresponding test result 142 from the engineering database 122 to the lifecycle database 132 may, for example, be performed seamlessly for a user, for example, of the lifecycle database 132 or the lifecycle management system 118′. In some examples, triggering to perform the test, and importing the corresponding test result 142 from the engineering database 122 to the lifecycle database 132 may be performed seamlessly from the lifecycle database 132 or the lifecycle management system 118′. This functionality considerably facilitates the management of lifecycle information 130 of the physical system 150 now even including triggering or managing tests and test results 142 that further improves the traceability and the verifiability, but also the persistence of the engineering process of the physical system 150.

In some examples, the lifecycle UI 116′ may be displayed on the user's computer, such as a laptop, handheld, personal computer, or the like, that is communicatively connected with the lifecycle database 132 or the lifecycle management system 118′ that may be cloud-based and, for example, run on a data center, server farm, or the like. Hence, the user may trigger performing the test using his or her computer via the lifecycle UI 116′ (e.g., the UI element 137 displayed on his or her computer). The lifecycle UI 116′ or, more specifically, the UI element 137 may sometimes be understood as a connector providing a link to the engineering database 122 or the engineering system 118 and allowing for triggering processes in the engineering database 122 or in the engineering system 118 (e.g., triggering performing the test). Herein, in some examples, the lifecycle UI 116′ (e.g., the UI element 137) or this specific connector may run locally on the computer of the user. This specific connector may involve a Uniform Resource Locator (URL), colloquially termed a web address, that may be a reference to a web resource that specifies its location on a computer network and a mechanism for retrieving the web resource. URLs occur most commonly to reference web pages (http) but are also used for file transfer (ftp), email (mailto), database access (JDBC), and many other applications.

In some examples, the UI element 137 or the mentioned specific connector may be, include, or be included by a button or a toolbar.

In some examples, the application software component 106 and/or the processor 102 may further be configured to: send a trigger signal to the engineering database (122) upon the captured user intent; and perform the test using the respective test case 140 and generate the respective test result 142 in the engineering database 122, respectively, upon receipt of the trigger signal by the engineering database 122.

Herein, the trigger signal may indicate to the engineering database 122 or to the engineering system 118 that the user provided his or the input indicating his or her intent to trigger performing the test. Once the trigger signal has been received by the engineering database 122, the engineering database 122 of the engineering system 118 may start performing the test.

In some examples, if the user has provided his or her input to the lifecycle database 132, the trigger signal may be sent from the lifecycle database 132 to the engineering database 122. In further examples, as explained above, the lifecycle UI 116′, (e.g., the UI element 137) or the above-mentioned specific connector may run locally on the computer of the user so that if the user has provided his or her input to the local computer of the user, the trigger signal may be sent from the local computer of the user to the engineering database 122. In yet further examples, a multi-user experience may be provided as follows. The lifecycle UI 116′ (e.g., the UI element 137) or the above-mentioned specific connector may run locally on the computer of the user, and the respective test result 142 may be imported to the local computer of the user. Hence, only this user may access the respective test result 142 (e.g., by displaying the respective test result 142 to this user on a display of the local computer of the user). The user may then expose the respective test result 142 to the lifecycle database 132 or the lifecycle system 118′ so that the respective test result 142 may become a commonly consumable object of the lifecycle database 132 or the lifecycle system 118′ (e.g., by making the respective test result 142 visible to a team of users of the lifecycle database 132 or the lifecycle system 118′). The mentioned exposure of the respective test result 142 to the lifecycle database 132 or the lifecycle system 118′ may, for example, be achieved by copying or importing the respective test result 142 from the user's local computer to the lifecycle database 132. Once the respective test result 142 is available in the lifecycle database 132, also the team of users of the lifecycle database 132 or the lifecycle system 118′ has full visibility of the traceability, and persistent storage of the respective test result 142 may be safeguarded. Herein, the team of users may include users with different roles, such as developers, (test) managers, product owners, etc. of the physical system 150, but also customers sometimes. This multi-user experience may add yet more value to the engineering process of the physical system 150, because it may overcome challenges that may occur in other approaches. According to this, often some (e.g., groups of) users of the lifecycle database 132 or the lifecycle system 118′ may not have access to the engineering database 122 or the engineering system 118 so that these (e.g., groups of) users may not directly or easily see the respective test result 142. In all the three above examples, triggering to perform the test and, as described above, importing the corresponding test result 142 from the engineering database 122 to the lifecycle database 132 may be performed seamlessly for a user (e.g., of the lifecycle database 132 or the lifecycle management system 118′). In some examples, triggering to perform the test and importing the corresponding test result 142 from the engineering database 122 to the lifecycle database 132 may be performed seamlessly from the lifecycle database 132 or the lifecycle management system 118′.

By way of example, the application software component 106 and/or the processor 102 may further be configured to provide a respective engineering artifact placeholder 138 and a respective test case placeholder 139 in the lifecycle database 132. The respective engineering artifact placeholder 138 and the respective test case placeholder 139 represent the respective engineering artifact 124 and the respective test case 140 stored in the engineering database 122 in the lifecycle database 132, respectively. The application software component 106 and/or the processor 102 may further be configured to provide a respective first connector 160 and a respective second connector 162 for connecting the respective engineering artifact 124 and the respective test case 140 stored in the engineering database 122 directly or indirectly with the respective engineering artifact placeholder 138 and the respective test case placeholder 139 stored in the lifecycle database 132, respectively.

Using a respective engineering artifact placeholder 138 and a respective test case placeholder 139 that are stored in the lifecycle database 132 may, in some examples, facilitate directly or more conveniently managing (e.g., simple aspects of) engineering information 120 in the lifecycle database 132 or the lifecycle management system 118′ while still benefiting from comprehensive, professional engineering management through the engineering database 122 or the lifecycle management system 118.

Using the respective engineering artifact placeholder 138 and the respective test case placeholder 139 may, in some examples, be particularly beneficial if the engineering database 122 and the lifecycle database 132 may not always be connected to each other with a sufficiently fast data connection allowing for fast data transfer and data synchronization. For example, network interruptions may occur, a server may be used for providing the engineering data base 122 or the engineering system 118 and/or the lifecycle database 132, or the lifecycle management system 118′ may not always be available. Such unreliable data connection scenarios may make consistency and traceability of engineering-related information very challenging.

In this context, the respective first connector 160 for connecting the respective engineering artifact 124 stored in the engineering database 122 directly or indirectly with the respective engineering artifact placeholder 138 stored in the lifecycle database 132 may facilitate to achieve consistency and traceability of engineering-related information.

Analogously, the respective second connector 162 for connecting the respective test case 140 stored in the engineering database 122 directly or indirectly with the respective test case placeholder 139 stored in the lifecycle database 132 may contribute to achieving consistency and traceability of engineering-related information.

In some examples, the respective placeholder (e.g., the respective engineering artifact placeholder 138 and the respective test case placeholder 139) may be understood as an ALM surrogate that is available in the lifecycle database 134. Further, the respective placeholder may also be understood as a shadow model of the respective engineering artifact 124 and the respective test case 140 stored in the engineering database 122.

The respective placeholder (e.g., the respective engineering artifact placeholder 138 and the respective test case placeholder 139) may be, for example, be created or updated “on demand” (e.g., when a user of the lifecycle database 132 or of the lifecycle management system 118′ may need the respective placeholder or the updated respective placeholder). The creation or update of the respective placeholder may, for example, be triggered by the user through a second UI element in the lifecycle UI 116′. In further examples, the respective engineering artifact placeholder 138 and/or the respective test case placeholder 139 may be linked to the respective lifecycle artifact 134 stored in the lifecycle database 132.

In further examples, if an amendment is made to the respective engineering artifact 124 and/or the respective test case 142 that results in a new or deleted dependency or link to the respective lifecycle artifact 134, the corresponding connector or link may be created or deleted, respectively. In such examples, analogously, the respective placeholder may be created or deleted, respectively. For example, if the respective test case 142 is amended such that the respective test case 142 for the first time (or no longer) relates to the respective lifecycle artifact 134, then the respective test case placeholder 139 may be created (or deleted) in the lifecycle database 132. The respective second connector 162 that connects the respective test case 142 stored in the engineering database 122 to the respective test case placeholder 139 stored in the lifecycle database 132 may then be created (or deleted). Additionally, links or connections of the respective test case placeholder 139 to the respective lifecycle artifact 134 and the respective test result 142 stored in the lifecycle database 132 may be created (or deleted). By way of example, the creation or deletion of the respective placeholder or connections or links of the respective placeholder to other elements stored in the lifecycle database 132 may, for example, be triggered by the user through the second or a third UI element in the lifecycle UI 116′. By way of example, in the interest of data persistence and traceability, deleted items and the different states of amended items as well as the mentioned first and second connectors 160, 162 may be stored in the lifecycle database 132.

In some examples, the application software component 106 and/or the processor 102 may further be configured to provide a respective lifecycle artifact placeholder 126 in the engineering database 122. The respective lifecycle artifact placeholder 126 represents the respective lifecycle artifact 134 stored in the lifecycle database 132 in the engineering database 122. The application software component 106 and/or the processor 102 may further be configured to provide a respective third connector 164 for connecting the respective lifecycle artifact 134 stored in the lifecycle database 132 directly or indirectly with the respective lifecycle artifact placeholder 126 stored in the engineering database 122.

Achieving consistency and traceability of engineering-related information may, for example, further be facilitated with the respective lifecycle artifact placeholder 126. The respective lifecycle artifact placeholder 126 may be understood as an engineering surrogate that is available in the engineering database 124. Further, the respective lifecycle artifact placeholder 126 may also be understood as a shadow model of the respective lifecycle artifact 134 stored in the lifecycle database 132.

In some examples, the respective lifecycle artifact placeholder 126 may be linked or connected to the respective engineering artifact 124 and the respective test case 140 stored in the engineering database 122.

Respective lifecycle artifact placeholder 126, in addition to using the respective engineering artifact placeholder 138, may, in some examples, be beneficial in the context of a challenging data connection between the engineering database 122 and the lifecycle database 132.

By way of example, in the interest of data persistence and traceability, deleted items and the different states of amended items as well as the mentioned third connector 164 may be stored in the engineering database 122 and if copied or imported to the lifecycle database 132, too. The third connector 164 may, for example, be stored in the lifecycle database 132.

In some examples, in case of at least one deficiency of the engineered physical system 150, the application software component 106 and/or the processor 102 may be further configured to: provide information on the respective deficiency of the physical product 150; determine at least one piece of engineering-related information of the engineered physical system 150, the engineering-related information of the engineered physical system 150 including the respective engineering artifact 124, the respective lifecycle artifact 134, the respective test case 140, and the respective test result 142 that has been generated throughout the engineering process of the physical system 150 and is related to the provided information on the respective deficiency; and display the determined, respective piece of engineering-related information and, optionally, the information on the respective deficiency of the engineered physical system 150 to the user in the lifecycle UI 116′.

The respective deficiency may, for example, include complaints or issues raised by customers of the engineered physical system 150, but also errors, malfunctions, non-conformances, etc. of the engineered physical system 150 that may result in poor performance of the engineered physical system 150 or even dangers caused by the engineered physical system 150. Herein, the engineered physical system 150 may, for example, be understood as a physical system 150 for that the engineering process has been completed and optionally that has already been produced and made available or delivered to the customer.

If the engineered physical system 150 suffers from a respective deficiency, information on the respective deficiency may be provided, for example, indicating what sort of malfunction or complaint the engineered physical system 150 suffers from. Based on the provided information, a suitable piece of engineering-related information of the physical system 150 may be determined, whereby the engineering-related information includes the respective engineering artifact 124, the respective lifecycle artifact 134, the respective test case 140, and the respective test result 142. In some examples, the determination of the suitable piece of engineering-related information may be coarse-grained and rather unspecific so that no sophisticated algorithm may be used and a rather large number of suitable pieces of engineering-related information may be determined. In further examples, a more sophisticated algorithm may be applied to the provided information to identify potentially relevant pieces of engineering-related information. The more sophisticated algorithm may take into account the relevant component of a compound physical system 150 or a technical domain of the deficiency (e.g., mechanical, electronic, or geometric issues of the engineered physical system 150) to suggest only the relevant piece(s) of engineering-related information that are related to the mentioned relevant component or technical domain.

The determined, respective piece(s) of engineering-related information may then be displayed to the user for further evaluation, optionally including the information on the respective deficiency of the engineered physical system 150. Hence, a root cause analysis that facilitates identifying and solving the problem underlying the deficiency of the engineered physical system 150 may be supported.

In further examples, the application software component 106 and/or the processor 102 may further be configured to engineer, model, simulate, and/or analyze the physical system 150 using the engineering information 120, the lifecycle information 130, the respective test case 140, and the respective test result 142.

Engineering, modeling, simulating, and/or analyzing the physical system 150 may, by way of example, include considering the time-varying behavior of the dynamical, physical system 150. Such physical systems 150 may, for example, be described by ordinary differential equations or partial differential equations. A simulation or calculation run may solve the state-equation system to find the behavior of the state variables over a specified period of time. The equation(s) may be solved through numerical integration methods to produce the transient behavior of the state variables. Simulation of dynamic physical systems 150 may predict the values of model-system state variables, as the values of model-system state variables are determined by the past state values. This relationship may be described or characterized by an according model of the physical system 150.

In some examples, engineering, modeling, simulating, and/or analyzing the physical system 150 may only be done after successful completion of respective test case 140.

In some examples, the application software component 106 and/or the processor 102 may further be configured to measure or determine the engineering information 120 of the physical system 150 (e.g., using a sensor, CAD data, communication data, etc.) relating to the physical system 150.

By way of example, some or all of the engineering information 120 (e.g., the respective engineering artifact 124) may be measured or determined using a sensor that may, for example, be suitable to measure or determine the respective engineering information 120, such as mechanical, thermal, etc. information of the physical system 150. Further, some or all of the engineering information 120 may be measured or determined using CAD data that may, for example, be determined, and in some cases read in, using a specification plate (e.g., an electronic specification plate) of the physical system 150. Herein, the (electronic) specification plate may include the CAD data or a sort of link that allows to access or download the CAD data. In further examples, some or all of the engineering information 120 may be measured or determined using communication data of the physical system 150 that is communicatively coupled to another device. Herein, the communication data may, for example, be used to determine control information or process-oriented information of the physical system 150.

In some examples, some or all of the engineering information 120 may be measured or determined using the respective (real) physical system 150 as indicated in FIG. 1, with the dashed line connecting the processor 102 of the engineering system 118 with the physical system 150.

Further, a computer-readable medium 170 that may include a computer program product 172 is depicted in FIG. 1, where the computer program product 172 may be encoded with executable instructions that, when executed, cause the computer system 100 to carry out the described method.

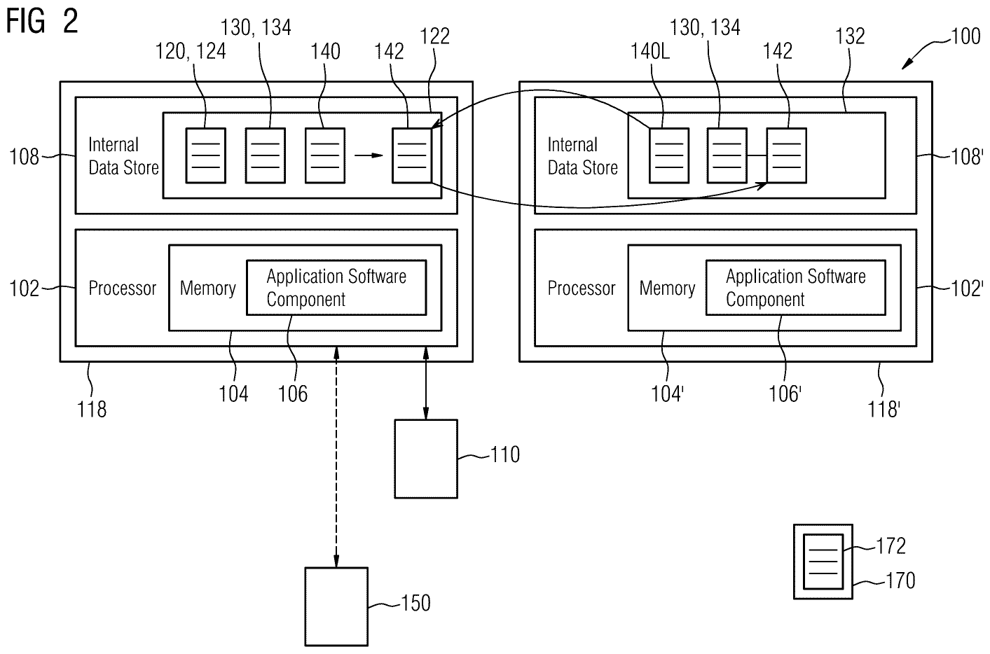

Referring now to FIG. 2, a functional block diagram of a second example data processing system 100 that facilitates engineering a physical system 150 in a product system is depicted.

As depicted in FIG. 2, a respective lifecycle test case 140L may be provided in the lifecycle database 132. The respective lifecycle test case 140L may then be imported from the lifecycle database 132 to the engineering database 122 and be stored in the engineering database 122 as the respective test case 140.

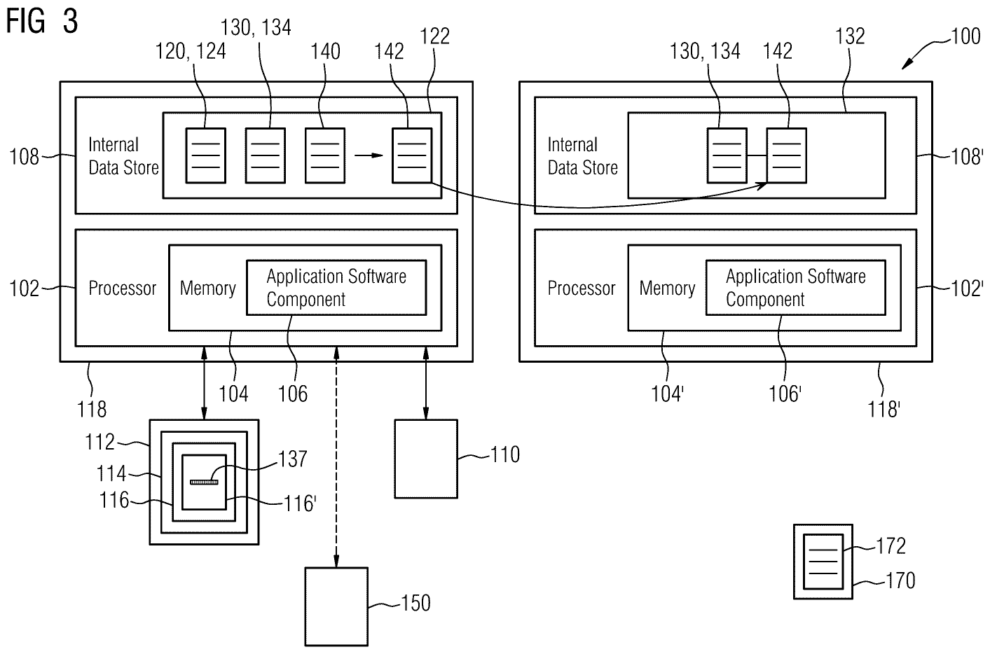

Referring now to FIG. 3, a functional block diagram of a third example data processing system 100 that facilitates engineering a physical system 150 in a product system is depicted.

As depicted in FIG. 3, a lifecycle UI 116′ may be provided or displayed to a user for interacting with the lifecycle database 132, where the lifecycle UI 116′ may optionally be included in the engineering user interface 116. The user may then provide user input through user interaction with the lifecycle UI 116′ (e.g., using the input device 110). For example, the user may indicate his or her intent to trigger performing the test using the respective test case 140 and generating a respective test result 142 in the engineering database 122. The provided user input may then be captured, for example, by the engineering system 118 or the lifecycle management system 118′. Upon the captured user intent, indicative of the user's intent to trigger performing the test using the respective test case 140 and generating a respective test result 142 in the engineering database 122, the test is performed using the respective test case 140, and a respective test result 142 is stored in the engineering database 122, respectively.

In some examples, a trigger signal may be sent to the engineering database 122 upon the captured user intent, whereby the test is performed using the respective test case 140, and the respective test result 142 is generated in the engineering database 122, respectively, upon receipt of the trigger signal by the engineering database 122.

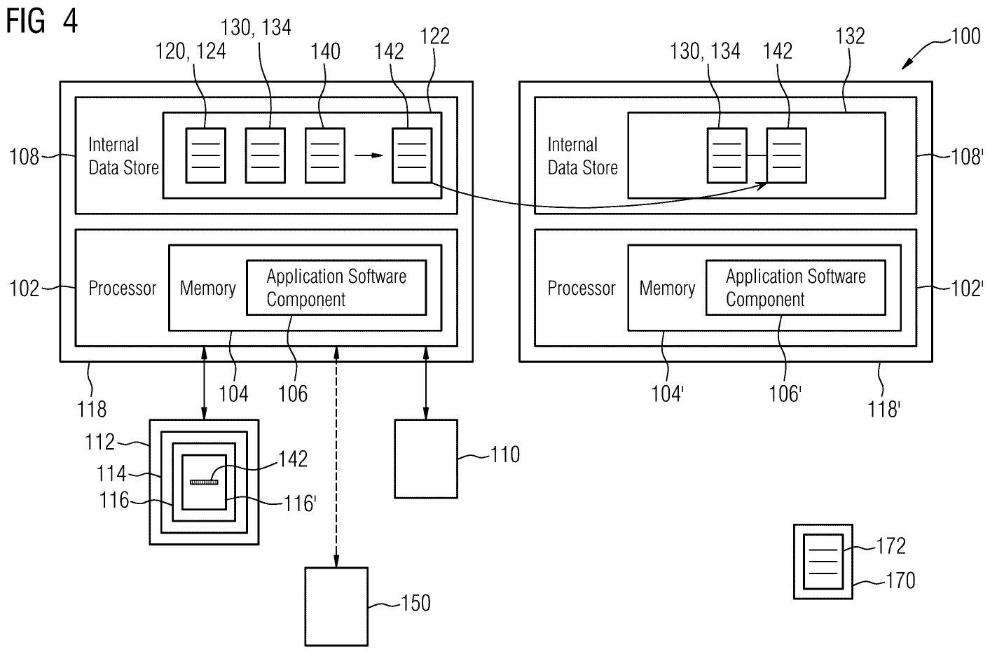

Referring now to FIG. 4, a functional block diagram of a fourth example data processing system 100 that facilitates engineering a physical system 150 in a product system is depicted.

As depicted in FIG. 4, the respective test result 142 may be displayed to the user of the lifecycle database 132 or the lifecycle management system 118′ in the lifecycle user interface 116′ that optionally may be included in the engineering user interface 116. Optionally, the respective lifecycle artifact 134 or other engineering-related information related to the respective test result 142 may be displayed to the user in the lifecycle user interface 116′.

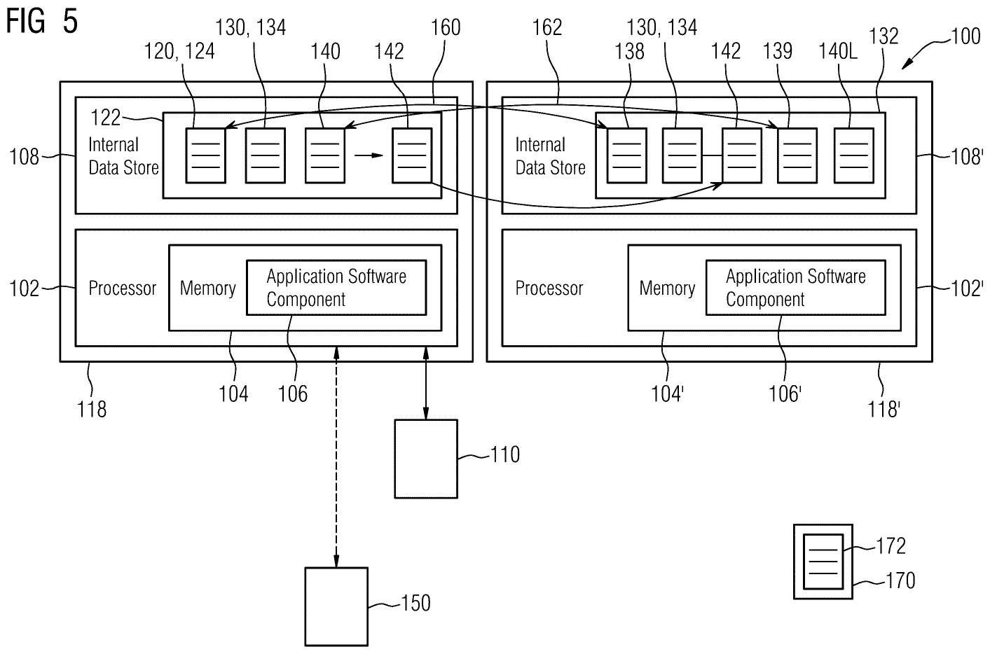

Referring now to FIG. 5, a functional block diagram of a fifth example data processing system 100 that facilitates engineering a physical system 150 in a product system is depicted.

As depicted in FIG. 5, a respective engineering artifact placeholder 138 and a respective test case placeholder 139 may be provided in the lifecycle database 132. Herein, the respective engineering artifact placeholder 138 stored in the lifecycle database 132 may represent the respective engineering artifact 124 stored in the engineering database 122. Further, the respective test case placeholder 139 stored in the lifecycle database 132 may represent the respective test case 140 stored in the engineering database 122.

A respective first connector 160 may connect the respective engineering artifact 124 stored in the engineering database 122 directly or indirectly with the respective engineering artifact placeholder 138 stored in the lifecycle database 132. Further, a respective second connector 162 may connect the respective test case 140 stored in the engineering database 122 directly or indirectly with the respective test case placeholder 139 stored in the lifecycle database 132.

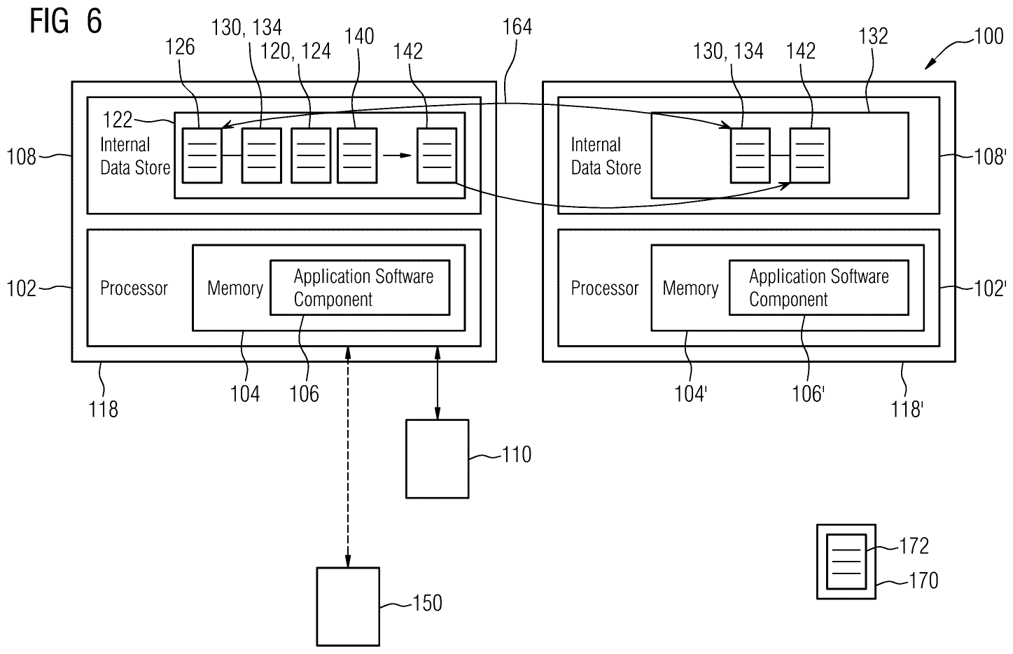

Referring now to FIG. 6, a functional block diagram of a sixth example data processing system 100 that facilitates engineering a physical system 150 in a product system is depicted.

As depicted in FIG. 6, a respective lifecycle artifact placeholder 126 may be provided in the engineering database 122. Herein, the respective lifecycle artifact placeholder 126 may represent the respective lifecycle artifact 134 stored in the lifecycle database 132 in the engineering database 122.

A respective third connector 164 may connect the respective lifecycle artifact 134 stored in the lifecycle database 132 directly or indirectly with the respective lifecycle artifact placeholder 126 stored in the engineering database 122.

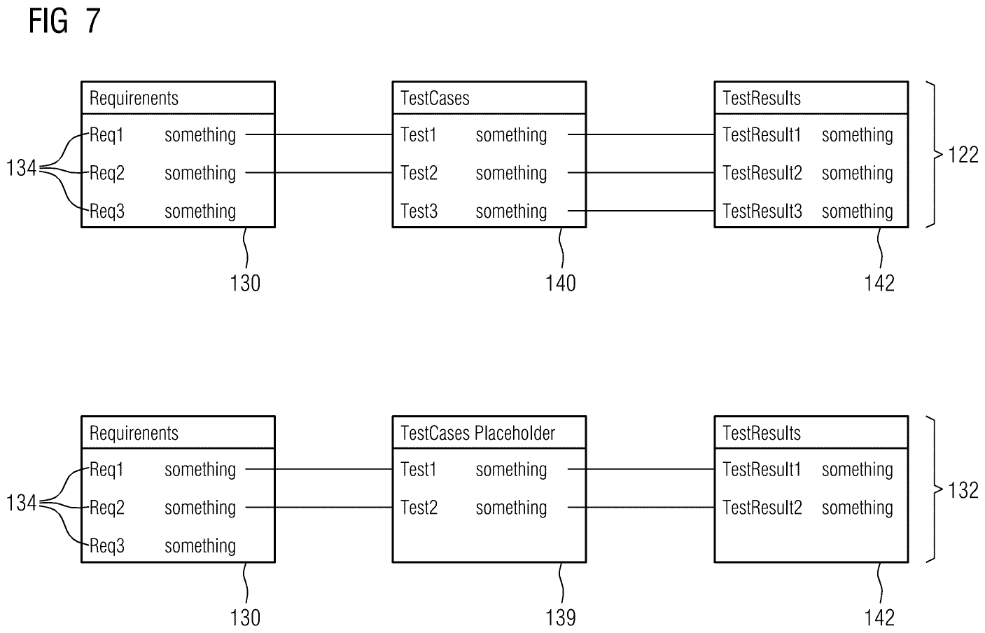

Referring now to FIG. 7, example relations of engineering information 130, test cases 140, and test results 142 in the context of facilitating engineering a physical system 150 in a product system are depicted.

As depicted in FIG. 7, lifecycle information 130 including three lifecycle artifacts 134, three test cases 140, and three test results 142 may be stored in the engineering database 122. Herein, two of the three lifecycle artifacts 134 are related and linked to two of the three test cases 140. The third lifecycle artifact 134 may, for example, not (yet) be related to a test case 140 or may, for example, be related to a different test case that is not depicted in FIG. 7. The third test case 140 may, for example, be related to an engineering artifact 124 included by engineering information 120 that is not depicted in FIG. 7. By performing the test using the respective test case 140 and, for example, taking into account the respective lifecycle artifact 134 and, for example, the respective engineering artifact 124, the respective test results 142 may be generated in the engineering database 122.

The lifecycle database 132 may include lifecycle information 130 including three lifecycle artifacts 134, two test case placeholders 139, and two test results 142. The two test case placeholders 139 and the two test results 142 may directly or indirectly be related to the two lifecycle artifacts 134 as depicted in FIG. 7. Herein, those test results 142 that are related to the requirement artifacts 134 stored in the lifecycle database 132 may be imported from the engineering database 122 to the lifecycle database 132 and may then be linked to the respective lifecycle artifact 134 stored in the lifecycle database 132.

Further, the respective test case placeholder 139 may be provided in the lifecycle database 132 to represent the respective test case 140 stored in the engineering database 122 in the lifecycle database 132. This may, for example, be done using a respective second connector 162 for connecting the respective test case 140 stored in the engineering database 122 directly or indirectly to the respective test case placeholder 139 stored in the lifecycle database 132, as explained in the context of FIG. 5.

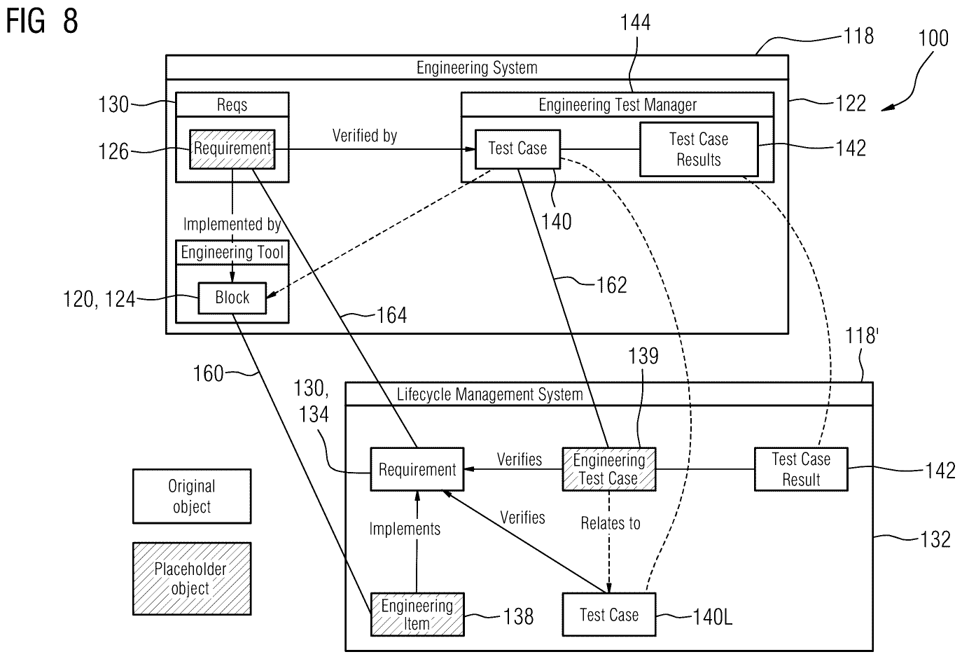

Referring now to FIG. 8, a schematic block diagram of a seventh example data processing system 100 that facilitates engineering a physical system 150 in a product system is depicted.

As depicted in FIG. 8, the data processing system includes an engineering system 118 including an engineering database 122 as well as the lifecycle management system 118′ including lifecycle database 132.

In the engineering database 122, engineering information 120 including an engineering artifact 124 may be engineered with an engineering tool. The engineering information 120 implements lifecycle information 130 including a lifecycle artifact placeholder 126 that may be verified by a test case 140. To this end, an engineering test manager (tool) 144 may run or execute the test case 140 to generate test (case) results 142.

In the lifecycle database 132, a partially similar arrangement of data may be found. Lifecycle information 130 including a lifecycle artifact 134 is stored in the lifecycle database 132, where an engineering artifact placeholder 138 (or the connected engineering artifact 124 stored in the engineering database 122) implements information stored in the lifecycle artifact 134, and where a test case placeholder 139 may verify the lifecycle artifact 134. The test results 142 stored in the engineering database 122 are also stored in the lifecycle database 132, where the test results 142 stored in the lifecycle database 132 are indirectly linked with the lifecycle artifact 134 via the test case placeholder 139 that are both stored in the lifecycle database 132.

The engineering artifact 124 stored in the engineering database 122 is connected with the engineering artifact placeholder 138 stored in the lifecycle database 132 via a first connector 160. Further, the test case 140 stored in the engineering database 122 is connected with the test case placeholder 139 stored in the lifecycle database 132 via a second connector 162. And the lifecycle artifact 134 stored in the lifecycle database 132 is connected with the lifecycle artifact placeholder 126 stored in the engineering database 122 via a third connector 164.

Additionally, a lifecycle test case 140L is stored in the lifecycle database 132, whereby the lifecycle test case 140L may, for example, be developed by a user using the lifecycle management system 118′ or may be provided from elsewhere. The lifecycle test case 140L may, in some examples, be imported from the lifecycle database 132 to the engineering database 122 and be stored as the test case 140 in the engineering database 122.

Further, as indicated in FIG. 8, the lifecycle artifact placeholder 126, the engineering artifact placeholder 138, and the test case placeholder 139 may be understood as placeholder objects, sometimes referred to as surrogates or shadow models, as explained above. The other elements may be understood as original objects that may be created and managed originally in the respective system (e.g., either the engineering system 118 or the lifecycle management system 118′).

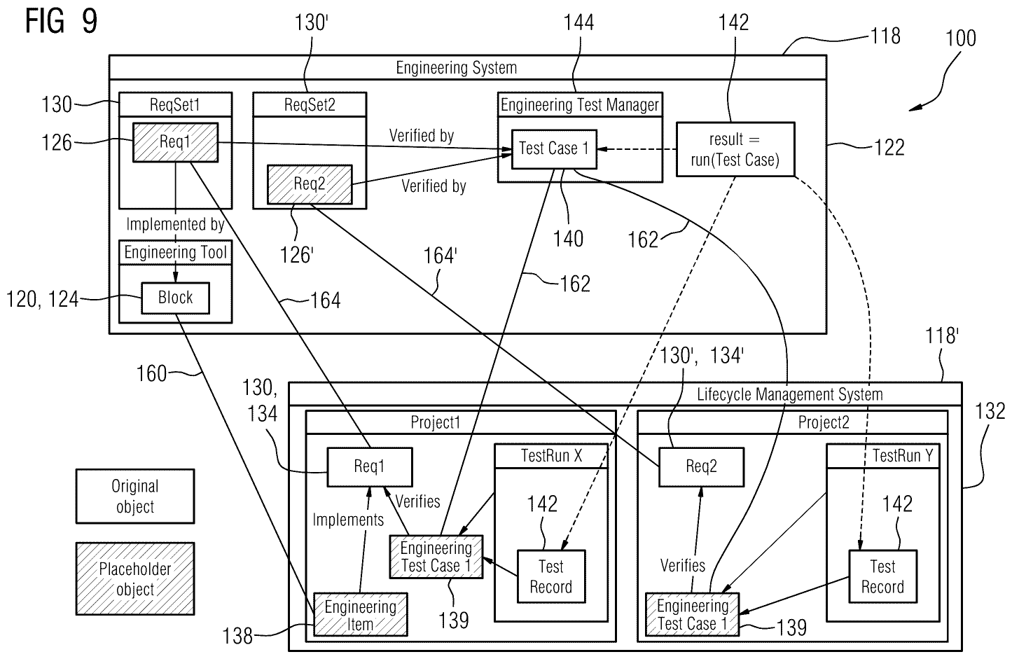

Referring now to FIG. 9, a schematic block diagram of an eighth example data processing system 100 that facilitates engineering a physical system 150 in a product system is depicted.

As depicted in FIG. 9, there are two sets of lifecycle information 130, 130′ including a respective lifecycle artifact placeholder 126, 126′ that may each be verified by the test case 140. Only the first set of lifecycle information 130 is implemented by the engineering information 120 including the engineering artifact 124. In the lifecycle management system 118′ and the lifecycle database 132, there are two separate projects, one for the first set of requirements 130 and one for the second set of requirements 130′. Herein, the first project basically has the same structure including the same connectors 160, 162, 164 as the items stored in the lifecycle database 132 of the seventh example data processing system 100 depicted in FIG. 8, whereby there is no lifecycle test case 140L in the first project. The second project is similar to the first project; however, in the second project, there is no engineering artifact placeholder 138 since the second set of lifecycle information 130′ including the lifecycle artifact 134′ is not (yet) implemented by a respective engineering artifact 124.

The test case 140 stored in the engineering database 122 may be represented in the lifecycle database 132 by two test case placeholders 139, whereby one of the two test case placeholders 139 is included in the first project and the other of the two test case placeholders 139 is included by the second project. Accordingly, the test results 142 stored in the engineering database 122 include the test results 142 for the first set of requirements information 130 and the test results 142 for the second set of requirements information 130′ as indicated in FIG. 9, with “result=run(TestCase)”. Hence, the test results 142 stored in the engineering database 122 may be understood as the above-mentioned test report. In some examples, the complete test results 142 may be imported to both projects, while in other examples, only the respective part of the complete test results 142 may be imported to the respective project. The test results 142 for the first set of requirements information 130 may be imported to the first project as indicated in FIG. 9, with “TestRun X”, and the test results 142 for the second set of requirements information 130′ may be imported to the second project, as indicated in FIG. 9 with “TestRun Y”.

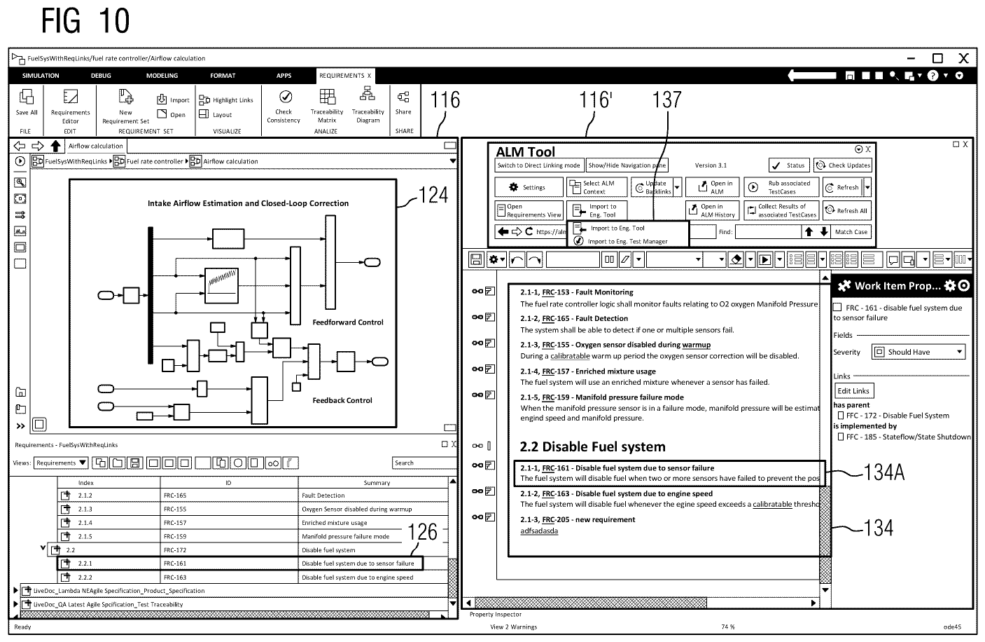

Referring now to FIG. 10, a sample UI that facilitates engineering a physical system 150 in a product system is depicted.

The depicted UI includes an engineering UI 116 and a lifecycle UI 116′, where some engineering artifacts 124 and a related lifecycle artifact placeholder 126 are displayed in the engineering UI 116. Lifecycle artifacts 134 corresponding to the engineering artifacts 124 are displayed in the lifecycle UI 116′, where the lifecycle artifact 134A may relate to the lifecycle artifact placeholder 126 as both mention “Disable fuel system due to the sensor failure”.

A UI element 137 may be displayed in the lifecycle UI 116′, and the user may select or click on the UI element 137 to provide his or the input to trigger performing the test using the respective test case 140 and generating the respective test result 142 in the engineering database 122. Once the corresponding user intent has been captured (e.g., by the lifecycle database 132 or the lifecycle management system 118′), the test may be performed accordingly in the engineering database 122.

In FIG. 10, the UI element 137 is accessible via the button “Import to Engineering” and the selection of the option “Import to Eng. Tool” or “Import to Eng. Test Manager”. Further, FIG. 10 depicts an “Update Backlinks” button in the lifecycle UI 116′ (e.g., in the vicinity of the UI element 137), whereby this button may correspond to the above-mentioned second UI element that may create or update the respective engineering artifact placeholder 138 and/or the respective test case placeholder 139. In addition, the lifecycle UI 116′ may further include a “Clean Up” button (e.g., depicted in FIG. 10 as “Refresh” or “Refresh All”), whereby this button may correspond to above-mentioned third UI element that may create or delete the respective placeholder, connections, or links of the respective placeholder to other elements stored in the lifecycle database 132.

As depicted in FIG. 10, the UI element 137 (and other UI elements like the above-mentioned second UI element) may be included in a toolbar (cf., in FIG. 10, “ALM Tool” box of the lifecycle UI 116′).

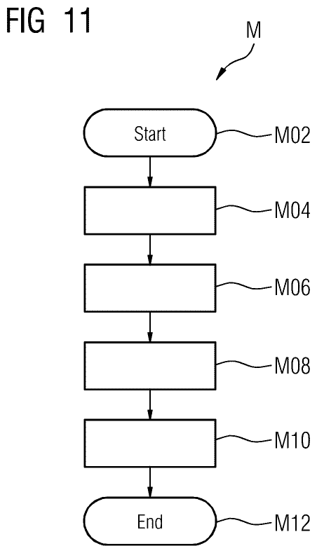

Referring now to FIG. 11, a flow diagram of an example methodology that facilitates engineering a physical system in a product system is depicted. The methodology M may start at M02 and may include several acts carried out through operation of at least one processor.

These acts may include an act M04 of providing engineering information, lifecycle information, and at least one test case win an engineering database, where the engineering information is related to physical, mechanical, electrical, electronic, hydraulic, thermal, control, electric power, and/or process-oriented information of the physical system. The lifecycle information is related to the conception, requirements, uses cases, issues, design, realization, and/or service information of the physical system. A respective engineering artifact included by the engineering information, a respective lifecycle artifact included by the lifecycle information, and/or a compliance of the respective engineering artifact with the respective lifecycle artifact may be tested using the respective test case. An act M06 of providing the lifecycle information in a lifecycle database is provided. An act M08 of performing the test using the respective test case and generating a respective test result in the engineering database, respectively, is provided. An act M10 of storing the respective test result in the lifecycle database and linking the respective test result to the respective lifecycle artifact stored in the lifecycle database, respectively, is provided. At M12, the methodology may end.

The methodology M may include other acts and features discussed previously with respect to the computer-implemented method of engineering a physical system.

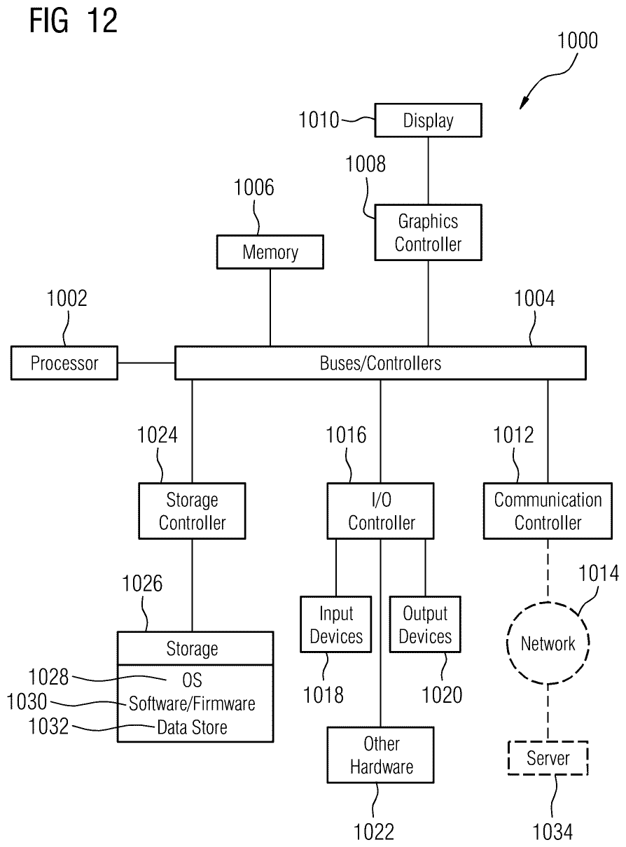

FIG. 12 depicts a block diagram of a data processing system 1000 (also referred to as a computer system) in that an embodiment may be implemented, for example, as a portion of a product system, and/or another system operatively configured by software or otherwise to perform the processes as described herein. The data processing system 1000 may include, for example, the computer or IT system or data processing system 100 mentioned above. The data processing system depicted includes at least one processor 1002 (e.g., a CPU) that may be connected to one or more bridges/controllers/buses 1004 (e.g., a north bridge, a south bridge). One of the buses 1004, for example, may include one or more I/O buses such as a PCI Express bus. Also connected to various buses in the depicted example may include a main memory 1006 (RAM) and a graphics controller 1008. The graphics controller 1008 may be connected to one or more display devices 1010. In some embodiments, one or more controllers (e.g., graphics, south bridge) may be integrated with the CPU (e.g., on the same chip or die). Examples of CPU architectures include IA-32, x86-64, and ARM processor architectures.

Other peripherals connected to one or more buses may include communication controllers 1012 (e.g., Ethernet controllers, WiFi controllers, cellular controllers) operative to connect to a local area network (LAN), Wide Area Network (WAN), a cellular network, and/or other wired or wireless networks 1014 or communication equipment.

Further components connected to various busses may include one or more I/O controllers 1016 such as USB controllers, Bluetooth controllers, and/or dedicated audio controllers (e.g., connected to speakers and/or microphones). Various peripherals may be connected to the I/O controller(s) (e.g., via various ports and connections) including input devices 1018 (e.g., keyboard, mouse, pointer, touch screen, touch pad, drawing tablet, trackball, buttons, keypad, game controller, gamepad, camera, microphone, scanners, motion sensing devices that capture motion gestures), output devices 1020 (e.g., printers, speakers), or any other type of device that is operative to provide inputs to or receive outputs from the data processing system. Many devices referred to as input devices or output devices may both provide inputs and receive outputs of communications with the data processing system. For example, the processor 1002 may be integrated into a housing (e.g., a tablet) that includes a touch screen that serves as both an input and display device. Further, some input devices (e.g., a laptop) may include a plurality of different types of input devices (e.g., touch screen, touch pad, keyboard). Other peripheral hardware 1022 connected to the I/O controllers 1016 may include any type of device, machine, or component that is configured to communicate with a data processing system.

Additional components connected to various busses may include one or more storage controllers 1024 (e.g., SATA). A storage controller may be connected to a storage device 1026 such as one or more storage drives and/or any associated removable media that may be any suitable non-transitory machine usable or machine-readable storage medium. Examples include nonvolatile devices, volatile devices, read only devices, writable devices, ROMs, EPROMs, magnetic tape storage, floppy disk drives, hard disk drives, solid-state drives (SSDs), flash memory, optical disk drives (CDs, DVDs, Blu-ray), and other known optical, electrical, or magnetic storage devices drives and/or computer media. Also, in some examples, a storage device such as an SSD may be connected directly to an I/O bus 1004 such as a PCI Express bus.

A data processing system in accordance with an embodiment of the present disclosure may include an operating system 1028, software/firmware 1030, and data stores 1032 (e.g., that may be stored on a storage device 1026 and/or the memory 1006). Such an operating system may employ a command line interface (CLI) shell and/or a graphical user interface (GUI) shell. The GUI shell permits multiple display windows to be presented in the graphical user interface simultaneously, with each display window providing an interface to a different application or to a different instance of the same application. A cursor or pointer in the graphical user interface may be manipulated by a user through a pointing device such as a mouse or touch screen. The position of the cursor/pointer may be changed and/or an event, such as clicking a mouse button or touching a touch screen, may be generated to actuate a desired response. Examples of operating systems that may be used in a data processing system may include Microsoft Windows, Linux, UNIX, iOS, and Android operating systems. Also, examples of data stores include data files, data tables, relational database (e.g., Oracle, Microsoft SQL Server), database servers, or any other structure and/or device that is capable of storing data that is retrievable by a processor.

The communication controllers 1012 may be connected to the network 1014 (not a part of data processing system 1000), which may be any public or private data processing system network or combination of networks, as known to those of skill in the art, including the Internet. Data processing system 1000 may communicate over the network 1014 with one or more other data processing systems such as a server 1034 (also not part of the data processing system 1000). However, an alternative data processing system may correspond to a plurality of data processing systems implemented as part of a distributed system in that processors associated with a number of data processing systems may be in communication via one or more network connections and may collectively perform tasks described as being performed by a single data processing system. Thus, when referring to a data processing system, such a system may be implemented across a number of data processing systems organized in a distributed system in communication with each other via a network.

Further, the term “controller” may be any device, system, or part thereof that controls at least one operation, whether such a device is implemented in hardware, firmware, software, or some combination of at least two of the same. The functionality associated with any particular controller may be centralized or distributed, whether locally or remotely.

In addition, data processing systems may be implemented as virtual machines in a virtual machine architecture or cloud environment. For example, the processor 1002 and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system may vary for particular implementations. For example, the data processing system 1000 in this example may correspond to a computer, workstation, server, PC, notebook computer, tablet, mobile phone, and/or any other type of apparatus/system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The processor described herein may be located in a server that is remote from the display and input devices described herein. In such an example, the described display device and input device may be included in a client device that communicates with the server (e.g., and/or a virtual machine executing on the server) through a wired or wireless network (e.g., that may include the Internet). In some embodiments, such a client device, for example, may execute a remote desktop application or may correspond to a portal device that carries out a remote desktop protocol with the server in order to send inputs from an input device to the server and receive visual information from the server to display through a display device. Examples of such remote desktop protocols include Teradici's PCoIP, Microsoft's RDP, and the RFB protocol. In such examples, the processor described herein may correspond to a virtual processor of a virtual machine executing in a physical processor of the server.

As used herein, the terms “component” and “system” are intended to encompass hardware, software, or a combination of hardware and software. Thus, for example, a system or component may be a process, a process executing on a processor, or a processor. Additionally, a component or system may be localized on a single device or distributed across a number of devices.

Also, as used herein, a processor corresponds to any electronic device that is configured via hardware circuits, software, and/or firmware to process data. For example, processors described herein may correspond to one or more (or a combination) of a microprocessor, CPU, FPGA, ASIC, or any other integrated circuit (IC) or other type of circuit that is capable of processing data in a data processing system, that may have the form of a controller board, computer, server, mobile phone, and/or any other type of electronic device.

Those skilled in the art will recognize that, for simplicity and clarity, the full structure and operation of all data processing systems suitable for use with the present disclosure are not being depicted or described herein. Instead, only so much of a data processing system as is unique to the present disclosure or necessary for an understanding of the present disclosure is depicted and described. The remainder of the construction and operation of data processing system 1000 may conform to any of the various current implementations and practices known in the art.

The words or phrases used herein should be construed broadly, unless expressly limited in some examples. For example, the terms “include”, “includes”, “comprise”, and “comprise,” as well as derivatives thereof, provide inclusion without limitation. The singular forms “a”, “an”, and “the” are intended to include the plural forms as well, unless the context clearly indicates otherwise. Further, the term “and/or” as used herein refers to and encompasses any and all possible combinations of one or more of the associated listed items. The term “or” is inclusive, meaning and/or, unless the context clearly indicates otherwise. The phrases “associated with” and “associated therewith,” as well as derivatives thereof, may mean to comprise, be comprised within, interconnect with, contain, be contained within, connect to or with, couple to or with, be communicable with, cooperate with, interleave, juxtapose, be proximate to, be bound to or with, have, have a property of, or the like.

Also, although the terms “first”, “second”, “third”, and so forth may be used herein to describe various elements, functions, or acts, these elements, functions, or acts should not be limited by these terms. Rather, these numeral adjectives are used to distinguish different elements, functions, or acts from each other. For example, a first element, function, or act may be termed a second element, function, or act, and, similarly, a second element, function, or act may be termed a first element, function, or act, without departing from the scope of the present disclosure.

In addition, phrases such as “processor is configured to” carry out one or more functions or processes, may be that the processor is operatively configured to or operably configured to carry out the functions or processes via software, firmware, and/or wired circuits. For example, a processor that is configured to carry out a function/process may correspond to a processor that is executing the software/firmware, that is programmed to cause the processor to carry out the function/process, and/or may correspond to a processor that has the software/firmware in a memory or storage device that is available to be executed by the processor to carry out the function/process. A processor that is “configured to” carry out one or more functions or processes may also correspond to a processor circuit particularly fabricated or “wired” to carry out the functions or processes (e.g., an ASIC or FPGA design). Further, the phrase “at least one” before an element (e.g., a processor) that is configured to carry out more than one function may correspond to one or more elements (e.g., processors) that each carry out the functions and may also correspond to two or more of the elements (e.g., processors) that respectively carry out different ones of the one or more different functions.

In addition, the term “adjacent to” may be that an element is relatively near to but not in contact with a further element, or that the element is in contact with the further portion, unless the context clearly indicates otherwise.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method of engineering a physical system, the method being computer-implemented, the method comprising:
providing engineering information, lifecycle information, and at least one test case in an engineering database, wherein the engineering information is related to physical information, mechanical information, electrical information, electronic information, hydraulic information, thermal information, control information, electric power information, process-oriented information, or any combination thereof of the physical system, wherein the lifecycle information is related to conception information, requirements information, use cases information, issues information, design information, realization information, service information, or any combination thereof of the physical system, and wherein a respective engineering artifact included in the engineering information, a respective lifecycle artifact included in the lifecycle information, a compliance of the respective engineering artifact with the respective lifecycle artifact, or any combination thereof is testable using the respective test case;
providing the lifecycle information in a lifecycle database;
performing the test using the respective test case and generating a respective test result in the engineering database, respectively; and
storing the respective test result in the lifecycle database and linking the respective test result to the respective lifecycle artifact stored in the lifecycle database, respectively.

2. The method of claim 1, further comprising:
providing a respective lifecycle test case in the lifecycle database; and
importing the respective lifecycle test case from the lifecycle database to the engineering database and storing the respective lifecycle test case in the engineering database as the respective test case.

3. The method of claim 1, further comprising:
providing at least one parameter of the respective test case in the engineering database,
wherein the respective parameter includes input data, expected output data, a number of repetitions, information on a callback, or any combination thereof.

4. The method of claim 3, further comprising:
storing the provided, respective parameter of the respective test case in the lifecycle database; and
linking the respective parameter of the respective test case to the respective test case stored in the lifecycle database.

5. The method of claim 1, further comprising:
providing a lifecycle user interface (UI) to a user for interacting with the lifecycle database;
capturing an intent of the user, such that performing the test using the respective test case and generating a respective test result in the engineering database, respectively, are triggered; and
performing the test using the respective test case and generating a respective test result in the engineering database, respectively, upon the captured intent of the user.

6. The method of claim 5, further comprising:
sending a trigger signal to the engineering database upon the captured intent of the user; and
performing the test using the respective test case and generating the respective test result in the engineering database, respectively, upon receipt of the trigger signal by the engineering database.

7. The method of claim 1, further comprising:
providing a respective engineering artifact placeholder and a respective test case placeholder in the lifecycle database, the respective engineering artifact placeholder and the respective test case placeholder representing the respective engineering artifact and the respective test case stored in the engineering database in the lifecycle database, respectively; and
providing a respective first connector and a respective second connector for connecting the respective engineering artifact and the respective test case stored in the engineering database directly or indirectly with the respective engineering artifact placeholder and the respective test case placeholder stored in the lifecycle database, respectively.

8. The method of claim 1, further comprising:
providing a respective lifecycle artifact placeholder in the engineering database, the respective lifecycle artifact placeholder representing the respective lifecycle artifact stored in the lifecycle database in the engineering database; and
providing a respective third connector for connecting the respective lifecycle artifact stored in the lifecycle database directly or indirectly with the respective lifecycle artifact placeholder stored in the engineering database.

9. The method of claim 1, further comprising in case of at least one deficiency of the engineered physical system:
providing information on the at least one deficiency of the engineered physical system;
determining at least one piece of engineering-related information of the engineered physical system, the engineering-related information of the engineered physical system including the respective engineering artifact, the respective lifecycle artifact, the respective test case, and the respective test result that has been generated throughout the engineering process of the physical system and is related to the provided information on the respective deficiency; and
displaying the determined, respective piece of engineering-related information to the user in the lifecycle UI.

10. The method of claim 9, further comprising displaying the information on the at least one deficiency of the engineered physical system.

11. The method of claim 1, further comprising:
engineering, modeling, simulating, analyzing, or any combination thereof of the physical system using the engineering information, the lifecycle information, the respective test case, and the respective test result.

12. The method of claim 1, further comprising:
measuring or determining the engineering information of the physical system.

13. The method of claim 12, wherein measuring or determining the engineering information of the physical system comprises measuring or determining the engineering information of the physical system using a sensor, CAD data, communication data, or any combination thereof relating to the physical system.

14. A computer system comprising:
a processor configured to engineer a physical system, the processor being configured to engineer the physical system comprising the processor being configured to:
provide engineering information, lifecycle information, and at least one test case in an engineering database, wherein the engineering information is related to physical information, mechanical information, electrical information, electronic information, hydraulic information, thermal information, control information, electric power information, process-oriented information, or any combination thereof of the physical system, wherein the lifecycle information is related to conception information, requirements information, use cases information, issues information, design information, realization information, service information, or any combination thereof of the physical system, and wherein a respective engineering artifact included in the engineering information, a respective lifecycle artifact included in the lifecycle information, a compliance of the respective engineering artifact with the respective lifecycle artifact, or any combination thereof is testable using the respective test case;
provide the lifecycle information in a lifecycle database;
perform the test using the respective test case and generate a respective test result in the engineering database, respectively; and
store the respective test result in the lifecycle database and link the respective test result to the respective lifecycle artifact stored in the lifecycle database, respectively.

15. In a non-transitory computer-readable storage medium that stores instructions executable by one or more processors to engineer a physical system, the instructions comprising:
providing engineering information, lifecycle information, and at least one test case in an engineering database, wherein the engineering information is related to physical information, mechanical information, electrical information, electronic information, hydraulic information, thermal information, control information, electric power information, process-oriented information, or any combination thereof of the physical system, wherein the lifecycle information is related to conception information, requirements information, use cases information, issues information, design information, realization information, service information, or any combination thereof of the physical system, and wherein a respective engineering artifact included in the engineering information, a respective lifecycle artifact included in the lifecycle information, a compliance of the respective engineering artifact with the respective lifecycle artifact, or any combination thereof is testable using the respective test case;
providing the lifecycle information in a lifecycle database;
performing the test using the respective test case and generating a respective test result in the engineering database, respectively; and
storing the respective test result in the lifecycle database and linking the respective test result to the respective lifecycle artifact stored in the lifecycle database, respectively.

16. The non-transitory computer-readable storage medium of claim 15, wherein the instructions further comprise:
providing a respective lifecycle test case in the lifecycle database; and
importing the respective lifecycle test case from the lifecycle database to the engineering database and storing the respective lifecycle test case in the engineering database as the respective test case.

17. The non-transitory computer-readable storage medium of claim 15, wherein the instructions further comprise:
providing at least one parameter of the respective test case in the engineering database,
wherein the respective parameter includes input data, expected output data, a number of repetitions, information on a callback, or any combination thereof.

18. The non-transitory computer-readable storage medium of claim 17, wherein the instructions further comprise:
storing the provided, respective parameter of the respective test case in the lifecycle database; and
linking the respective parameter of the respective test case to the respective test case stored in the lifecycle database.

19. The non-transitory computer-readable storage medium of claim 15, wherein the instructions further comprise:
providing a lifecycle user interface (UI) to a user for interacting with the lifecycle database;
capturing an intent of the user, such that performing the test using the respective test case and generating a respective test result in the engineering database, respectively, are triggered; and
performing the test using the respective test case and generating a respective test result in the engineering database, respectively, upon the captured intent of the user.
